(19) United States
(12) Patent Application Publication
(10) Pub. No.: US 2005/0124154 A1
(43) Pub. Date: Jun. 9, 2005

(54) Method of forming copper interconnections for semiconductor integrated circuits on a substrate

(76) Inventors: Hyung-Sang Park, Seoul (KR); Sang-Won Kang, Daejeon (KR)

Correspondence Address: MARGER JOHNSON & MCCOLLOM, P.C., 1030 SW MORRISON STREET, PORTLAND, OR, 97205, US

(21) Appl. No.: 10/500,494

(22) PCT Filed: Dec. 28, 2002
(86) PCT No.: PCT/KR02/02468

(30) Foreign Application Priority Data
Dec. 28, 2001 (KR) 10-2001-0086955

(51) Int. Cl. H01L 21/4763; H01L 21/44

(52) U.S. Cl. 438/643; 438/653; 438/687

(57) ABSTRACT

A method for forming copper interconnection conductors for interconnecting integrated circuits on a substrate by forming a barrier layer or an adhesion layer or both having excellent adhesion property is disclosed. Ruthenium (Ru) and ruthenium alloys, and rhenium (Re) and rhenium alloys are proposed to use according to the present invention. Other metals proposed to use include nickel (Ni), platinum (Pt), osmium (Os), iridium (Ir) and their alloys, respectively.

### TECHNICAL FIELD

Present invention relates to a method for forming copper interconnecting conductors for semiconductor integrated circuits on a substrate.

### BACKGROUND ART

The design groundrules of minimum linewidths for patterning metallic interconnecting wires on a substrate are becoming tighter as the circuit density of semiconductor elements continue increasing, thereby the electrical resistance of the interconnecting metallic wires continue increasing resulting in slow semiconductor devices, and the improvement of such device performance is increasingly difficult to resolve without reducing the resistance of the interconnecting wires.

Recently the copper material that has much higher conductivity than the widely used aluminum has been used in order to produce semiconductor devices meeting the speed requirement for high density circuits.

Copper is a much harder metal than aluminum, and it is more difficult to etch than aluminum. Therefore, for forming copper intercormecting wire, a damascene structure that has necessary patterned depressions such as trenches and via holes formed by etching an insulating layer is used, where the trenches and holes are filled with copper material, and then the top surface is removed by using a chemical-mechanical polishing (CMP) process, thereby the necessary interconnecting copper conductors formation is completed.

However, the copper material is diffused easily and rapidly into an insulating layer such as silicon or silicon oxide, thereby formation of a barrier layer on the surface of the insulation layer into which a damascene structure is imbedded, is necessary prior to forming an aforementioned copper layer in order to prevent the occurrence of the diffusion of copper material into the insulation layer by making a direct contact between the insulating material and the copper material. The materials used for forming a barrier layer are required to have a good adhesion characteristics with the insulation layer having damascene structures, thereby the peeling-off phenomenon of the copper material filling the trenches and the via holes is eliminated during the CMP process. According to the conventional method, a barrier layer is formed using tantalum or tantalum-nitride on the surface of the insulation layer that forms the damascene structure. Such barrier layer is formed on the surface of a substrate typically using a sputtering method. Furthermore, a thin copper seed layer is formed on the surface of the barrier layer, using sputtering technique and then the damascene structure is filled with copper material without voids using electroplating technique followed by a CMP process to remove the excessive copper material on the surface, thereby exposing the necessary insulation material to form the desired copper interconnecting layer on a substrate.

The barrier layer and the copper seed layer formed by using aforementioned sputtering method has a good adhesion property. However, the sputtering method is not well suited for forming barrier and copper seed layers on a damascene structure with very narrow and deep trenches and via holes due to the inherent line-of-sight deposition property of the sputtering technique. More specifically, when the side walls of the damascene structure are not covered properly with a barrier layer, the copper material subsequently filling the trenches and via holes is diffused into the insulation material through the imperfections in the barrier layer, thereby the performance of the semiconductor devices degrades as well as the reliability of such devices decreases. When a sputtering technique is used for thoroughly covering the sidewalls of the trenches and via holes with a barrier layer, the bottom parts of the trenches and via holes as well as the top surface of the insulation layer on the substrate may be covered with an undesirablely thick barrier layer. Since the undesirably thick barrier layer formed at the bottom of the trenches and the via holes has a lower electrical conductivity, the electrical resistance of the resulting trenches and via holes increase, thereby the speed of the semiconductor devices decrease. Once the barrier layer is formed, a copper layer is formed on top of the barrier layer in order to fill the trenches and via holes. Subsequently, the undesirable portions of the copper and barrier layer formed on the insulation layer are removed using a chemical-mechanical polishing process, thereby the time required for removing the copper layer and the unnecessarily thick barrier layer by a CMP process reduces the productivity of the manufacturing of semiconductor devices and also increases the corresponding manufacturing cost.

On the other hand, the imperfections that may exist in the copper seed layer, may cause the formation of undesirable voids in the copper seed layer during the subsequent electroplating process, thereby such undesirable voids would reduce the reliability of the semiconductor devices. Furthermore, in case that the size of the openings of the via holes and the width of the trenches are very small and narrow, respectively, the so-called pinch-off phenomenon occurs around narrow top openings of the trenches and via holes, where the pinch-off phenomenon reduces the size of the top openings of the via holes and the width of the top openings of the trenches during the seed layer formation process, when the barrier layer is formed by using a sputtering method. Subsequently, if the top openings of the trenches and the via holes become small, so that the cross-sections of the top openings of the trenches and via holes become narrow due to the aforementioned pinch-off phenomenon have typically a “jar” shape, thereby it is difficult to fill such trenches and via holes with narrow top openings with copper material without creating undesirable voids.

Nevertheless, the afore-described void problem can be avoided by forming a barrier layer as well as a seed layer by using a metallic layer forming method resulting in a good step coverage. The main object of the present invention is to present such a film formation method. If a thin barrier layer is formed over the entire surface of a substrate, the resistance of the via holes and trenches may be reduced, thereby the speed of the semiconductor devices may be improved as well as the semiconductor device manufacturing cost may be reduced since the time required for removing the copper layer, the seed layer and the barrier layer by using a CMP process is reduced significantly, the corresponding productivity of the semiconductor device manufacturing is improved, and, as a result, the semiconductor device manufacturing cost is subsequently lowered.

Furthermore, since such method of forming a thin metallic layer with a good step coverage does not cause the so-called pinch-off phenomenon and, as a result, the top openings of the trenches and via holes are not narrowed down, the trenches and via holes can be easily filled with copper material without causing the formation of undesirable voids during the subsequent process of electroplating.

However, the aforementioned sputtering method has been used instead of an alterative method such as chemical vapor deposition (CVD) method with good step coverage for forming a copper layer as well as a barrier layer simply because of the poor adhesion problem between the barrier layer and the copper layer. In addition, the spattering method does not cause contamination problem at the boundary between the copper layer and the barrier layer, whereas the chemical vapor deposition (CVD) method creates the contaminant problem due to the contaminants such as carbon (C) and floure (F) at the boundary between the copper layer and the barrier layer. It has been presumed that the contaminants such as carbon (C) and floure (F) are the cause of a poor adhesion between the copper layer and the barrier layer. However, no chemical vapor deposition (CVD) method capable of depositing copper material without accumulating contaminants during the deposition process, has been disclosed.

However, a chemical vapor deposition method for forming a boundary region by using cobalt or ruthenium to improve the adhesion property between a copper layer and a substrate has been disclosed in the U.S. Pat. No. 6,365,502 by Paranjpe, et al. Since the electrical conductivity of the barrier layer for preventing the diffusion of copper material into an insulation layer is lower than the conductivity of copper, use of a thinner barrier is advantageous. The plasma-enhanced atomic layer deposition (PEALD) method promotes the nucleation process during the process of thin film formation, thereby use of this method is advantageous for forming a metallic layer with continuous crystalline property compared to a conventional chemical vapor deposition (CMP) method according to the present invention.

### DESCRIPTION OF THE PRESENT INVENTION

According to the present invention, a method for forming high reliability copper interconnecting conductors connecting high density semiconductor circuits on an insulation layer in which a damascene structure is pre-formed on a substrate by forming a barrier layer, a adhesion layer or both, where such layers have a high quality adhesion characteristics with a copper layer, is disclosed.

### DETAILED DESCRIPTION OF THE INVENTION

According to the present invention, in order to form the copper interconnection conductors interconnecting high density semiconductor devices and elements on a substrate, a barrier layer is formed using ruthenium (Ru) or ruthenium alloys by using an atomic layer deposition (ALD) method on the surface of an insulating layer on a substrate, and successively a copper layer is formed on the surface of a barrier layer, where the atomic ratio of said ruthenium alloys contain at least 50% or more of ruthenium (Ru), when ruthenium (Ru) alloys are used as a barrier layer or an adhesion layer or both. According to the present invention, a copper layer is formed using a plasma-enhanced atomic layer deposition (PEALD), using a chemical vapor deposition (CVD) method, using a chemical vapor deposition with iodine or iodine compound as a catalyst, or also using an electroplating method as well. According to the present invention, a copper layer can be formed using a combination of a chemical vapor deposition method and an electroplating method, and in such an order of processing. According to the present invention, in order to form a barrier layer, rhenium(Re) or rhenium alloys, are used, where the atomic ratio of said rhenium alloys contain at least 50% or more of rhenium when rhenium alloys are used as a barrier layer or an adhesion layer or both.

According to another aspect of the present invention, a method for forming metallic interconnection conductors for interconnecting semiconductor devices and elements on a substrate by forming a barrier layer on a patterned insulation layer and by forming an adhesion layer on the barrier layer by an atomic layer deposition (ALD) method using ruthenium (Ru) or ruthenium alloys, and on the adhesion layer, forming a copper layer as the main metallic layer for metallic interconnections of semiconductor devices and elements on a substrate, where the barrier layer is formed using one of TiN, Ta, TaN, TaNC, WN, WNC, Ti—Si—N and Ta—Si—N, and the atomic ratio of said ruthenium alloys contain at least 50% or more of ruthenium, and also according to the present invention, a plasma-enhanced atomic layer deposition (PEALD) method is preferably used instead of an atomic layer deposition (ALD) method, and also, for forming a copper layer, a chemical vapor deposition (CVD) method or a chemical vapor deposition method with iodine or iodine compound as a catalyst or an electroplating method or a combination of a chemical vapor deposition method and an electroplating method and in the same order of processing, where for forming said barrier layer, rhenium (Re) or rhenium alloys can be used instead of ruthenium (Ru) or ruthenium alloys where the atomic ratio of the ruthenium (Ru) alloys and rhenium alloys contain at least 50% or more of ruthenium (Ru) or rhenium (Re) respectively. According to the present invention, for forming a barrier layer, instead of using ruthenium or ruthenium alloys and rhenium (Re) or rhenium alloys, nickel(Ni), platinum(Pt), osmium(Os) iridium(Ir) and their alloys can be used.

### BRIEF DESCRIPTION OF THE DRAWINGS

FIG. 1 is a cross-sectional diagram of a substrate prior to processing an embodiment.

FIG. 2A is a cross-sectional diagram of a substrate after forming a barrier layer and an adhesion layer on a substrate in FIG. 1.

FIG. 2B is a cross-sectional diagram of FIG. 2A illustrating a process of treating the surface of the substrate of FIG. 2A using a catalyst.

FIG. 3 is a cross-section of a substrate in FIG. 2A or FIG. 2B after a copper layer is formed on the surface of the substrate in FIG. 2A or FIG. 2B.

### BEST MODE FOR CARRYING OUT THE PRESENT INVENTION

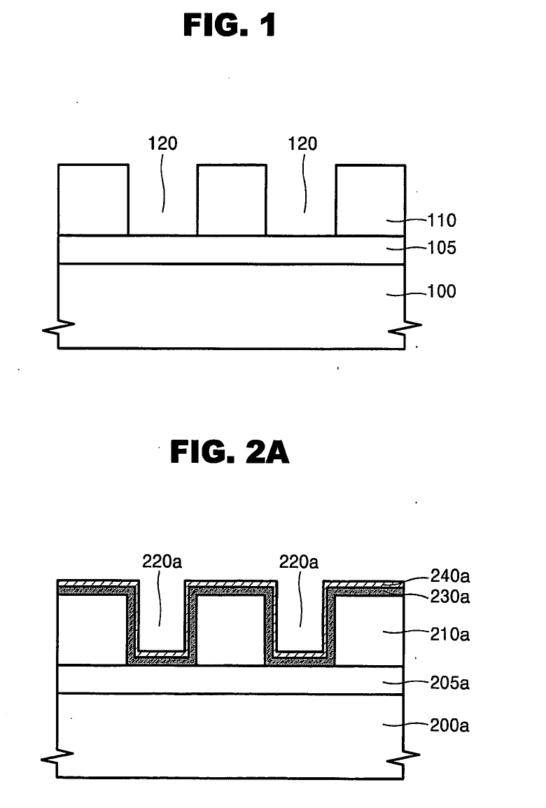

FIGS. 1 through 3 are the cross-sectional diagrams illustrating a method for forming copper interconnection conductors on a semiconductor substrate, according to the best modes for carrying out the present invention.

Referring to FIG. 1, as an example, a base layer 105 is formed on a single crystal silicon substrate 100. The base layer 105 may be a variety of insulation layers such as a silicon nitride layer or a silicon oxide layer used during the semiconductor device manufacturing processes or a variety of conductive layers of metals, conductive metallic oxides or a conducting layer including conductive semiconductor layers.

After an insulation layer 110 is formed on the base layer 105, the depression patterns 120 such as trenches and via holes in the insulation layer 110. Said insulation layer between two processing layers, where such insulation layer may be a silicon nitride layer or a silicon oxide layer. Said depression 120 such as trenches and via holes are a variety of depressions patterned onto the insulation layer 110, and such depressions are filled with copper material in subsequent processing steps, and also such depression 120 may be trenches for forming a conducting wire or a via hole for exposing the surface of a conducting layer for interconnections.

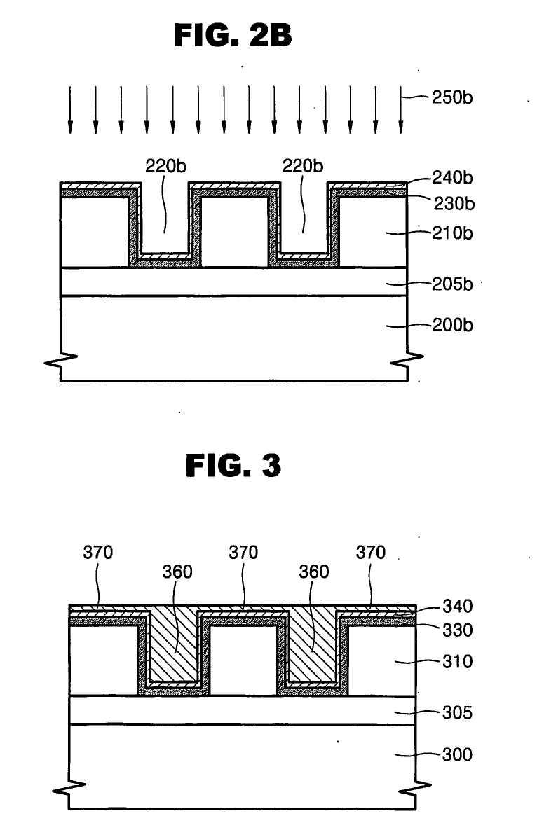

FIG. 2A is a cross-sectional diagram of a substrate after forming a barrier layer and an adhesion layer on the substrate in FIG. 1. Referring to FIG. 2A, a barrier layer 230a is formed on the entire surface of the semiconductor substrate 200a, on which necessary depressions 220a are pre-formed. Said barrier layer 230a is to prevent diffusion of the copper material to be formed on said depression as a subsequent steps of processing into the insulating layer 210a formed with, as an example, silicon oxide, thereby the copper interconnecting conductors can function as good conductors as desired, where for a barrier layer 230a a tantalum (Ta) material such as Ta or TaN, a titanium (Ti) material such as Ti or TiN, or a tungsten (W) material such as W or WN are primarily used. Also, ruthenium (Ru) or rhenium (Re), which have property of immiscibility with copper material and also of mechanically very strong material, can be used as a barrier layer 230a according to the present invention. Said barrier layer formed with Ti or Ta or W metals or such metallic nitride, can contain an atomic ratio from several to several tens of percent, preferably from several and up to 30%, according to the present invention.

As above-described, the barrier layer 230a can be formed using a physical vapor deposition (PVD) method such as sputtering technique, but such sputtering technique has a limitation due to its property of line-of-sight deposition for forming such a barrier layer when the top openings of the depressions 220a such as trenches and via holes are narrow and the depths of said depressions 220a are deep, thereby it is advantageous to use a chemical vapor deposition (CVD) method having an excellent step coverage property, or an atomic layer deposition (ALD) method, where a thin layer to a desired thickness is formed by repeated use of such an ALD method.

A plasma-enhanced atomic layer deposition (PEALD) method has been disclosed in a Korean Patent application KR02-73473, where a plasma RF power is applied for a given period of time during a source gas supply cycle and repeated this process in order to form a thin layer to a desired thickness. According to the present invention, a barrier layer can be formed by using said plasma-enhanced atomic layer deposition method. According to said plasma-enhanced atomic layer deposition (PEALD) method, a thin layer of film can be formed at a low temperature and the rate of film deposition can be increased by generating highly reactive radicals and ions, thereby such radicals and ions can participate in the reaction even if a source gase with low reactivity is used. In particular, in case that a very thin layer of film is to be formed, under the condition that crystals are formed, said plasma-enhanced atomic layer deposition facilitates nucleation, thereby it increases the density of nucleation, and as a result the substrate can be covered with a thin layer of film without faults. On the other hand, if the density of said nucleation is low, a compactly dense thin film is formed, the crystal grains have to be grown to significantly large sizes, thereby said crystal grains get closely clustered and thus a continuous film is formed. In turn, this process requires formation of a thick film in order to form a consistently continuously film. When a metallic film is to be formed, use of a plasma-enhanced atomic layer deposition (PEACD) method is advantageous for covering said substrate with a thin layer of film because crystals are easily formed at a low temperature according to the present invention.

Referring to FIG. 2A again, meanwhile, said adhesion layer 240a can be formed using one of the metallic elements and their alloys of non-carbonic metals such as ruthenium (Ru), rhenium (Re), nickel (Ni), palladium (Pd), osmium (Os), iridium (Ir) and platinum (Pt), where said each metallic alloy contains an atomic ratio of at least 50% or more of each non-carbonic metals. On the other hand, tantalum (Ti) or tantalum family of alloys, titanium (Ti) or titanium family of alloys, or tungsten (W) or tungsten family of alloys, may be used for forming a barrier layer (230a), but when a liquid form of copper source material such as (hfac) Cu(vtms) is used for subsequently forming a copper layer on top of said barrier layer 230a by using a chemical vapor deposition method, which procedure will be described later, the adhesion between said barrier layer 230a and said copper layer formed on said barrier layer 230a becomes poor, thereby said barrier layer 230a is “peeled-off” during the chemical-mechanical polishing process for removing the excessive copper material from the top surface of the substrate for a subsequent processing step, causing severe defects. The cause of said “peel-off” problem is presumable due to the presence of contaminants such as carbon and fluorine between said barrier layer 230a and said copper layer when an adhesion layer 240a is lacking. The afore-described tantalum (Ta) or tantalum family of alloys, titanium (Ti) or titanium family of alloys, tungsten (W) or a tungsten family of alloys, and their metallic nitrides and the materials containing a small amount of silicon react with the carbon material and easily forms carbides such as Ti—C, Ta—C, W—C or Si—C, thereby an adhesion layer 240a between said barrier layer 230a and said copper layer is preferably necessary using a non-carbonic metals that do not react with carbon to form their carbonides, thereby a good adhesion property between said barrier layer and said copper layer according to the present invention is expected.

In an experiment, according to the present invention, two barrier layers using TiN and TaN are formed on two substrates, respectively, followed by a formation of copper layers on each one of said barrier layer on the substrates heated at 200° C. by supplying (hfac)Cu(vtms) gas as a source gas for fives(5) minutes through a chemical vapor deposition, process after which said copper layer was “peeled-off” on a “scotch tope”. On the other hand, three adhesion layers of nickel (Ni), ruthenium (Ru) and, gold (Au) were formed on three substrates, and under the same condition and using same copper source material as above, copper layers are formed on each substrate, respectively, after which “scotch tape” tests were carried out. In this experiment, said scotch tape did not peel-off said copper layers.

Therefore, according to the present invention, in case that one of the non-carbide-forming metals such as ruthenium (Ru), rhenium (Re), nickel (Ni), palladium (Pd), osmium (Os), iridium (Ir) and platinum (Pt) or one of the alloys of the said non-carbonic metals listed above containing an atomic ratio of at least 50% or more of the above metals, respectively, is used as an adhesion layer 240a followed by a formation of a copper layer using (hfac)Cu(vtms) as a source material through a chemical vapor deposition method, an excellent adhesion property between said barrier layer and said copper layer is obtained compared to the cases with nickel (Ni), ruthenium (Ru) and gold (Au) as described previously, because the non-carbonic metals listed above do not presumably form carbides. Of course, since ruthenium (Ru) or rhenium (Re) are used as a barrier layer, an adhesion layer is not necessary because ruthenium (Ru) and rhenium (Re) are immiscible or are not diffused into copper, and also have excellent mechanical strength according to the present invention.

A chemical vapor deposition method for speedily depositing copper material on a substrate using iodine as a catalyst and using (hfac)Cu(vtms) as a copper precursor is disclosed in the Korean Patent application No. 98-53575.

If the material used for said adhesion layer 240a works also positively with said iodine as a catalyst in a chemical vapor deposition, the depressions 220a can be speedily filled with copper material by using the method disclosed in the Korean Patent Application No. 00-1232 according to the present invention. The effect of iodine or iodine compound as a catalyst shows when copper layer of film is formed on a substrate covered with a thin layer of nickel (Ni) or ruthenium (Ru) by using said chemical vapor deposition method using (hfac)Cu(vtms) at 150° C. as a copper deposition source material after said substrate is treated with iodine or iodine compound as a catalyst according to the present invention. Referring to FIG. 2B, a semiconductor substrate 200b, on which an adhesion layer 240b is pre-formed, is treated with iodine or iodine compound as a catalyst 250b.

Referring to FIG. 3 subsequently, a copper layer 360 is formed using (hfac)Cu(vtms) as a copper precursor on the surface of an adhesion layer 340 by using said chemical vapor deposition method.

After completion of the formation of a copper deposition a process of chemical-mechanical polishing is carried out on the resultant copper surface in order to remove all the copper material except for the depressions 320 area to form a copper interconnection layer according to the present invention.

Alternatively, instead of using said chemical vapor deposition method, an electroplating method alone or a combination of said chemical vapor deposition method and an electroplating method may be sequentially used for forming a copper layer on said barrier layer or said adhesion layer according to the present invention. Ordinarily, a chemical-mechanical polishing process is successively performed to carry out as the subsequent processing step.

A part of preferred embodiments of the present invention have been described above. However, these descriptions are not intended to limit the principles and concepts of the present invention. Those who are in the art should be able to generate or formulate variations of the principles and concepts within the scope of the present invenation. More specifically, according to the present invention, the depressions such as trenches and via holes for use of forming copper interconnections can have various shapes and arrangements, and also without treating a substrate with iodine as a catalyst as shown in FIG. 2B, a copper layer can be formed directly on the adhesion layer 240B by using a conventional chemical vapor deposition method as well.

### EMBODIMENT 1

Using the plasma-enhanced atomic layer deposition (PEALD) method disclosed in the Korean Patent Application No. 01-46802, two thin films of TiN and Ru, respectively, are formed. The reactor pressure is kept at 3 Torr and the temperature of a substrate located in a reactor is maintained at 350° C. While a mixture of argon (Ar) gas, nitrogen (N₂) gas and hydrogen (H₂) gas is being continuously supplied into said reactor, the source gas TiCl₄ is supplied for 0.3 second. After 1.1 seconds later, a plasma is turned on for 0.8 second at the power level of 150 watts and at the frequency of 13.56 MHz. After 0.8 second later, the source gas TiCl₄ is again supplied for the beginning of the subsequent cycle, where the total basic cycle time is 3.0 seconds. A thin layer of TiN film is formed by repeating said basic cycle of said 3.0 seconds 450 times.

Successively, while argon (Ar) gas is being continuously supplied into said reactor, the temperature of said substrate covered with said thin layer of TiN is kept at 250° C., ruthenium source gas is supplied to the reactor for 2.0 seconds by feeding argon (ar) gas as a transport gas into a bubbler, containing bis(ethylcyclopentadienyl) ruthenium which temperlature is maintained at 85° C., connected to said reactor in which said substrate is located. The supply of argon (Ar) gas to said bubbler is ceased, and said reactor is purged with argon (Ar) gas for 2.0 seconds, said substrate is exposed to an oxidation environment by feeding oxygen (O₂) gas into said reactor for 2.0 seconds, and then said reactor is purged again by feeding argon (Ar) gas into said reactor for 2.0 seconds. And then hydrogen (H₂) gas is supplied into said reactor for 1.0 second, said substrate is reduced by exposing said substrate to hydrogen (H₂) plasma by feeding hydrogen (H₂) gas for 2.0 seconds while a plasma is turned on at the power level of 150 watts at the frequency of 13.56 MHz, said plasma is turned off, and said reactor is purged with argon (Ar) gas for 2.0 seconds, thereby the total process cycle time is 13.0 seconds. A ruthenium (Ru) thin layer is formed by repeating 300 times said 13.0 second process cycle of the sequence of ruthenium source gas supply-oxidation-reduction.

Successively, without directly exposing said ruthenium thin layer of film to open air, immediately after the formation of said ruthenium thin layer of film through the afore-described processing steps, said substrate covered with said ruthenium thin layer of film is treated with iodinethane as a catalyst, transported to a reactor in a vacuum environment and a copper layer of film is formed on the surface of said substrate by supplying the copper source gas (hfac)(Cu)(vtms) into said reactor for 5.0 seconds, which reactor is loaded with said substrate and the temperature of said substrate is maintained at 150° C.

The copper layer of thin film formed through the processing steps described above, has an excellent adhesion property. Said copper film did not only peel off during the scotch-tape adhesion tests, but also only a scratch on the surface of said copper film remained without being peeled off when said copper film surface was scratched with a sharp end of a nail. According to the present invention, the processes of treating said substrate with a catalyst and of forming a copper layer of thin film can be performed using same reactor.

### EMBODIMENT 2

A nickel(Ni) layer of thin film is formed using said plasma-enhanced atomic layer deposition method and by performing such nickel film formation by using the thin film formation apparatus disclosed in the Korean Patent Application No. 01-46802. A reactor pressure is maintained at 3 Torr, the temperature of a silicon substrate covered with an SiO₂ layer of thin film of 100 nm in thickness and also a TiN layer of thin film of 15 nm in thickness is kept at 165+ C. A nickel (Ni) source gas is supplied to said reactor by feeding argon (Ar) gas as a transport gas into a bubbler containing bis (cyclopentadienyl) nickel heated at 50° C., the supply of argon (Ar) transport gas to said bubbler is stopped, said reactor is purged with argon (Ar) gas, H₂O gas is supplied into said reactor, said reactor is purged again with argon (Ar) gas, and successively, while H₂ gas is being fed into said reactor a plasma is turned on at the power level of 150 watts at the frequency of 13.56 MHz so that said substrate is placed in a reduction environment. Said plasma is turned off and said reactor is again purged with argon (Ar) gas, thereby a nickel (Ni) layer of thin film of 15 nm in thickness is formed by repeating 80 times such process cycle of the sequence of nickel source gas supply-H₂O gas supply-reduction. Said nickel layer of thin film formed through the processing steps described above is directly transported into a reactor without directly exposing it to open air, and the surface of said substrate is covered with a copper layer of thin film of 1.0 μm in thickness by using (hfac)(Cu)(vtms) as a copper precursor and also using said plasma-enhanced atomic layer deposition method with iodine as a catalyst as described previously. Said copper layer of thin film formed this way was tested for standard scotch-tape adhesion tests, and excellent results were obtained.

According to the present invention, the processes of treating said substrate with a catalyst and of forming a copper layer of thin film can be performed using same reactor.

### EMBODIMENT 3

A TaNC layer of thin film and an Ru layer of thin film are formed using said plasma-enhanced atomic layer deposition (PEALD) method and by performing such TaNC and Ru film formation by using the thin film formation apparatus disclosed in the Korean Patent Application No. 01-46802 same as in Embodiments 1 and 2. A reactor pressure is maintained at 3 Torr, the temperature of a semiconductor substrate within said reactor is kept at 250° C. While a mixture of argon (Ar) and hydrogen (H₂) gases is being continuously supplied into said reactor, tert-butylimidotris(diethylamido) tantalum [TBTDET] as a tantalum source gas is supplied into said reactor for 0.5 second, followed by a time gap of 0.5 second, a plasma is turned on for 0.7 second at the RF power level of 150 watts and at the frequency level of 13.56 MHz, and the RF power is turned off. After a time gap of 0.4 second, nitrogen (N₂) gas is supplied for 0.5 second, during which period the plasma is turned on, at the RF power level of 150 watts and at 13.56 MHz. After 0,4 second later said source gas TBTDET is supplied again for a new cycle. The total cycle time required is 3.0 seconds. By repeating such 3.0 second of basic processing cycle, a thin layer of TaNC film is formed.

Said substrate on which said TaNC film formed by following the sequence of the processing steps described above, is heated at 250° C., and on said TaNC layer of thin film a Ru layer of thin film is formed by using the plasma-enhanced atomic layer deposition method in Embodiment 1. Successively, a copper layer of thin film is formed on said TaNC film formed above by using the copper precursor (hfac)Cu(vtms) as a copper source gas, by maintaining said substrate at 200° C. and by using the same plasma-enhanced atomic layer deposition method used in the previous two Embodiments.

The thin layer of copper film formed this way has shown excellent adhesion property, passing the commonly used scotch-tape tests and also only scratch marks were left without the copper film being peeled off when said copper film surface is scratched with a sharp point of a nail.

According to the present invention, the processes of treating said substrate with a catalyst and of forming a copper layer of thin film can be performed using same reactor.

Industrial Applicability

According to the present invention, barrier layers or adhesion layers can be formed by using a plasma-enhanced atomic layer deposition method, and also on such barrier layers or adhesion layers, a copper layer can be formed using the plasma-enhanced atomic layer deposition method described in the Embodiments, resulting in excellent adhesion property for semiconductor product manufacturing applications of copper interconnection conductors.

1. A method for forming copper interconnection conductors for interconnecting integrated circuits on a substrate, comprising the steps of;
forming a barrier layer using ruthenium (Ru) or rhenium (Re) or their alloys on the surface of an insulation layer on said substrate by using an atomic layer deposition (ALD) method, and
forming a copper layer on top of said barrier layer.

2. The method of claim 1, wherein said ruthenium (Ru) alloys contain an atomic ratio of at least 50% or more of ruthenium (Ru).

3. The method of claim 1, wherein in place of said atomic layer deposition method, a plasma-enhanced atomic layer deposition (PEALD) method is used.

4. The method of claim 1, wherein said copper layer of thin film is formed using a chemical vapor deposition (CVD) method.

5. The method of claim 1, wherein said copper layer of thin film is formed using a chemical vapor deposition method with a treatment of iodine or iodine compound as a catalyst.

6. The method of claim 1, wherein said copper layer of thin film is formed by using an electroplating method.

7. The method of claim 1, wherein said copper layer of thin film is formed by using a chemical vapor deposition method and an electro-plating method.

8. The method of claim 1, wherein rhenium (Re) or rhenium alloys are used in place of ruthenium (Ru) or ruthenium alloys.

9. The method of claim 8, wherein said rhenium alloys contain an atomic ratio of at least 50% or more of rhenium.

10. A method for forming copper interconnection conductors for interconnecting integrated circuits on a substrate, comprising the steps of;
forming a barrier layer on the surface of a patterned insulation layer on a substrate,
forming an adhesion layer on said barrier layer using ruthenium (Ru) or ruthenium alloys by using an atomic layer deposition method, and
forming a copper layer of thin film on the surface of said adhesion layer.

11. The method of claim 10, wherein said barrier layer is formed using one of the materials including TiN, Ta, TaN, TaNC, WN, WNC, Ti—Si—N. and Ta—Si—N.

12. The method of claim 10, wherein said ruthenium (Ru) alloys contain an atomic ratio of at least 50% or more of ruthenium.

13. The method of claim 10, wherein in place of said atomic layer deposition method, a plasma-enhanced atomic layer deposition method is used.

14. The method of claim 10, wherein said copper layer of thin film is formed using a chemical vapor deposition (CVD) method.

15. The method of claim 10, wherein said copper layer of thin film is formed using a chemical vapor deposition method with a treatment of iodine or iodine compound as a catalyst.

16. The method of claim 10, wherein said copper layer of thin film is formed by using an electroplating method.

17. The method of claim 10, wherein said copper layer of thin film is formed by using a chemical vapor deposition method and an electroplating method.

18. The method of claim 10, wherein rhenium (Re) or rhenium IS alloys are used in place of ruthenium (Ru) or ruthenium alloys.

19. The method of claim 18, wherein said rhenium alloys contain an atomic ratio of at least 50% or more of rhenium.

20. The method of claim 10, wherein in place of ruthenium (Ru) or ruthenium alloys, one of the materials including nickel (Ni), platinum (Pt), osmium (Os), iridium (Ir) or their alloys of said each metal is used for forming a barrier layer.
